(19) United States
(12) Patent Application Publication
(10) Pub. No.: US 2025/0293130 A1
(43) Pub. Date: Sep. 18, 2025

(54) DIE PACKAGE WITH ENTANGLED VERTICAL INTERCONNECTS COUPLED TO A ROUTING SUBSTRATE FOR REDUCED ROUTING SUBSTRATE LAYERS, AND RELATED INTEGRATED CIRCUIT (IC) PACKAGES AND FABRICATION METHODS

(71) Applicant: QUALCOMM Incorporated, San Diego, CA (US)

(72) Inventors: Aniket Patil, San Diego, CA (US); Manuel Aldrete, Encinitas, CA (US); Joan Rey Villarba Buot, Escondido, CA (US)

(21) Appl. No.: 18/607,986

(22) Filed: Mar. 18, 2024

(51) Int. Cl. H01L 23/498; H01L 23/00; H01L 25/065

(52) U.S. Cl. CPC H01L 23/49822; H01L 23/49816; H01L 24/16; H01L 24/48; H01L 24/73; H01L 25/0657; H01L 2224/16145; H01L 2224/16245; H01L 2224/48145; H01L 2224/48245; H01L 2224/73257; H01L 2225/06506; H01L 2225/06517; H01L 2924/1431; H01L 2924/1434; H01L 2924/15311; H01L 2924/182

(57) ABSTRACT

Die package with entangled vertical interconnects coupled to a routing substrate for reduced routing substrate layers, and related IC packages and fabrication methods are disclosed. The die package includes a first die coupled to a routing substrate to provide signal routing paths to the first die. The die package includes entangled vertical interconnects coupled to metal interconnects in the routing substrate, which are angled metal interconnects with respect to the extending direction of the coupled metal interconnects. The entangled vertical interconnects can be coupled to respective metal interconnects in an interposer substrate to provide a signal routing path between the die package and the interposer substrate as part of an IC package. In this manner, it is not necessary for the interposer substrate or the routing substrate of the first die package to have entangled interconnects for interconnections between unaligned metal interconnects in the interposer substrate and the routing substrate.

### FIELD OF THE DISCLOSURE

The field of the disclosure relates to integrated circuit (IC) packages, and more particularly to IC packages that include an interposer substrate to facilitate electrical connections between multiple dies in the IC package.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a substrate as a routing substrate (e.g., a package substrate) to provide physical support and an electrical interface to the die(s). The die(s) is electrically interfaced to metal interconnects (e.g., metal traces) exposed in an upper layer of the substrate as part of signal routing paths. The substrate also includes one or more metallization layers that include metal interconnects (e.g., metal traces, metal lines) with vertical interconnect accesses (vias) coupling the metal interconnects together between adjacent metallization layers to provide electrical interfaces between the dies. If the substrate is a package substrate, the substrate also includes a lower, outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

Some IC packages are known as multiple (multi-) die IC packages, which include multiple dies included in the IC package for different purposes or applications. For example, a multi-die IC package may include a first, application die (e.g., a processor or system-on-a-chip (SoC), and a separate second die or IC package that provides supporting circuits for the application die. Splitting major applications/functions into separate dies is an alternative to putting circuits for all such applications/functions into a single die. Fabrication cost and complexity increase disproportionally with larger sized dies. For example, the second die or IC package may have a die with a power management circuit modem, a processor, or memory (e.g., double data rate (DDR) memory) as examples. These multi-die IC packages can be provided in the form of a three-dimensional (3D) IC (3DIC) package. The 3DIC package can include a first die coupled to a first, bottom package substrate and encapsulated in a mold layer. The 3DIC package can then include a second die or IC package that is coupled to the first die through an interposer substrate as part of a second die or IC package. The first and second dies may be provided in their own separate respective first and second die/IC packages that are stacked on and coupled to each other in a package-on-package (POP) arrangement. The interposer substrate is coupled to the mold layer of the first, bottom die package and disposed between the first and second die/IC packages. Vertical interconnects disposed in the mold layer of the first, bottom die package and adjacent to the first die in a lateral/horizontal direction(s) connect metal interconnects in the interposer substrate to metal interconnects in the second, upper die package to provide signal routing paths between the second die/IC package and the first die through their respective interposer and die substrates.

As the number of input/output (I/O) pins of a die(s) provided in a 3DIC package increases, the pitch of die interconnects of the die(s) and the vertical interconnects in the 3DIC package may not be able to be the same. For example, if the second, upper die of the 3DIC package has an increased number of I/O pins, the interconnects of the second, upper die cannot each be aligned with the vertical interconnects in a vertical direction for straight-on connections. However, it may not be possible or desired to reduce the pitch of the vertical interconnects using known or available fabrication methods given the aspect ratio of the vertical interconnects. In this regard, the electrical signal paths between the I/O pins of a die and the vertical interconnects in the 3DIC package may need to be entangled (i.e., not vertically aligned between its connections) to provide the necessary signal routing paths between the die and the interposer substrate. The entangled signal routing paths can be provided in the interposer substrate for example. However, providing entangled signal routing paths in the interposer substrate for connections between a die and the interposer substrate creates additional routing complexity and congestion in the interposer substrate. This can cause the interposer substrate to have to provide a larger area and/or larger number of metallization layers to support the entangled signal paths to provide sufficient signal routing paths and signal routing isolation, which may be undesirable.

### SUMMARY OF THE DISCLOSURE

Aspects disclosed herein include a die package with entangled vertical interconnects coupled to a routing substrate for reduced routing substrate layers. Related integrated circuit (IC) packages and fabrication methods are also disclosed. The die package includes a first die coupled to a routing substrate (e.g., a package substrate, an embedded trace substrate (ETS)) for providing signal routing paths between external interconnects and the first die. The die package can be provided as part of an IC package that also includes a second electrical component (e.g., second die or second IC package) coupled to the die package and an interposer substrate disposed between the second die and the die package. The interposer substrate has metal interconnects coupled to the second electrical component and the die package to provide signal routing paths between the second electrical component and the die package. For example, the IC package could be a three-dimensional (3D) IC (3DIC) package where the second electrical component is a second, upper die that is coupled to the die package as a first, bottom die package in a vertical direction. The 3DIC package could be a package-on-package (POP) assembly that includes a second, upper die package with the second, upper die coupled to the first, bottom die package.

In exemplary aspects, the die package includes entangled vertical interconnects that are coupled to metal interconnects in the routing substrate of the die package. Entangled vertical interconnects are vertical interconnects that are angled metal interconnects in the vertical direction between their coupled metal interconnects in the routing substrate of the die package. In this manner, the signal routing provided by the entangled vertical interconnects is not in a straight vertical direction between metal interconnects aligned in a straight vertical direction, but rather laterally offset in a horizontal direction between its coupled metal interconnects. In this manner, the entangled vertical interconnects are free from a design perspective to couple any metal interconnects together in an IC package even if such metal interconnects are not aligned in the vertical direction. Also, as an example, the entangled vertical interconnects can be in a mold layer of the die package that encompasses the first die in the die package and is disposed adjacent to the first die in the horizontal direction. The entangled vertical interconnects can be coupled to respective metal interconnects in an interposer substrate to provide a signal routing path between the die package and the interposer substrate. For example, metal interconnects in the interposer substrate may not be aligned with the metal interconnects of the routing substrate in the vertical direction such that straight vertical interconnects can be used to couple the metal interconnects of the interposer substrate to the metal interconnects of the routing substrate of the die package. Thus, the entangled vertical interconnects can provide signal routing paths between coupled metal interconnects in the interposer substrate and the routing substrate of the die package that are not vertically aligned to each other. For example, it may be desired for the die interconnects and metal interconnects of the interposer substrate to have a different pitch from the metal interconnects of the routing substrate of the die package.

In this manner, it is not necessary for the interposer substrate or the routing substrate of the die package to have entangled interconnects to support interconnections between the interposer substrate and the routing substrate that may not be vertically aligned and/or have the same pitch. In this manner, as an example, if the interposer substrate is provided to couple the second electrical component having die interconnects with a different pitch from the metal interconnects of the routing substrate, the entangled interconnects do not have to be provided in the interposer substrate or the first routing substrate. The entangled vertical interconnects can be provided as the vertical interconnects in the die package between the die package and the interposer substrate. For example, the entangled vertical interconnects may be disposed in a mold layer of the die package that is disposed on the routing substrate and encompasses and is laterally adjacent in the horizontal direction to the first die. As an example, the entangled vertical interconnects can be provided as wire bonds in the mold layer that are coupled to metal interconnects of the interposer substrate and the routing substrate. In this manner, the wire bonds are able to be bent at an angle to provide entangled vertical interconnects between the interposer substrate and the routing substrate.

In another exemplary aspect, the entangled vertical interconnects of the 3DIC package may be formed from wire bond loops each with their two ends coupled to a metal interconnect in the routing substrate. The wire bond loops can then be processed by grinding or otherwise removing a portion of the top section of the wire bond loop to form two separate wire bond vertical interconnects connected to the routing substrate. By removing a portion of the top section of the wire bond loops, each wire bond loop becomes two separate wire bonds each with unconnected ends. The interposer substrate is then coupled to the die package to couple the unconnected ends of the wire bonds to the interposer substrate to provide electrical signal routing paths between the interposer substrate and the routing substrate. The entanglement of the wire bonds is controlled by controlling the length, width, and location of the connections between the ends of the wire bond loops and the routing substrate to control the angle of the resulting wire bonds when the top sections of the wire bond loops are removed. The shape of the wire bonds is controlled such that when the top section of the wire bond loops is removed, the resulting unconnected ends are located in anticipated locations of metal interconnects in the interposer substrate to be connected when the interposer substrate is coupled to the die package.

In this regard, in one exemplary aspect, a die package is provided. The die package comprises a routing substrate extending in a first direction, the routing substrate comprising a first metallization layer comprising a plurality of first metal interconnects and a plurality of second metal interconnects. The die package also comprises a die comprising a plurality of die interconnects each extending in a second direction orthogonal to the first direction. Each die interconnect of the plurality of die interconnects is coupled to a first metal interconnect of the plurality of first metal interconnects. The die package also comprises a plurality of entangled vertical interconnects coupled to a second metal interconnect of the plurality of second metal interconnects. Each of the plurality of entangled vertical interconnects is disposed at an angle with respect to the second direction.

In another exemplary aspect, a method of fabricating an IC package is provided. The method comprises fabricating a die package, comprising providing a routing substrate extending in a first direction, the routing substrate comprising a first metallization layer comprising a plurality of first metal interconnects and a plurality of second metal interconnects; coupling each of a plurality of die interconnects of a die each extending in a second direction orthogonal to the first direction, to a first metal interconnect of the plurality of first metal interconnects; and coupling each of a plurality of entangled vertical interconnects to a second metal interconnect of the plurality of second metal interconnects. Each of the plurality of entangled vertical interconnects is disposed at an angle with respect to the second direction.

In another exemplary aspect, an IC package is provided. The IC package comprises a first die package. The first die package comprises a first routing substrate extending in a first direction, the first routing substrate comprising a first metallization layer comprising a plurality of first metal interconnects and a plurality of second metal interconnects. The IC package also comprises a first die comprising a plurality of first die interconnects each extending in a second direction orthogonal to the first direction. Each first die interconnect of the plurality of first die interconnects is coupled to a first metal interconnect of the plurality of first metal interconnects. The first die package also comprises a plurality of entangled vertical interconnects coupled to a second metal interconnect of the plurality of second metal interconnects. Each of the plurality of entangled vertical interconnects is disposed at an angle with respect to the second direction. The IC package also comprises an interposer substrate adjacent to the first die package in the second direction. The interposer substrate comprises a second metallization layer comprising a plurality of third metal interconnects each coupled to an entangled vertical interconnect of the plurality of entangled vertical interconnects.

### BRIEF DESCRIPTION OF THE FIGURES

FIGS. 1A and 1B are side views of an exemplary integrated circuit (IC) package that includes a die package with entangled vertical interconnects coupled to a routing substrate of the die package, wherein the die package is provided in an IC package and coupled to an interposer substrate to provide signal routing paths between a second electrical component coupled to the interposer substrate and the die package in the IC package;

FIG. 2 is a side view of another IC package with an interposer substrate having entangled interconnects coupled to a die package and a second die to provide signal routing paths between the second die and the die package;

FIG. 3A is a top view of the die package of the IC package in FIGS. 1A and 1B without the presence of the mold layer in the die package;

FIG. 3B is a side cross-sectional view of the die package in FIG. 3A across the A1-A1′ cross-section line in FIG. 3A;

FIG. 3C is a top view of the die package in FIG. 3A after top sections of wire bond loops are removed to form separate wire bonds as the entangled vertical interconnects coupled to the die package;

FIG. 3D is a side view of the die package in FIG. 3C with the entangled vertical interconnects as wire bonds encompassed in the mold layer of the die package;

FIG. 4 is a flowchart illustrating an exemplary process of fabricating a die package with entangled vertical interconnects coupled to a routing substrate of the die package, wherein the die package can be provided in an IC package and coupled to an interposer substrate to provide signal routing paths between a second electrical component coupled to the interposer substrate and the die package in the IC package, including, but not limited to, the die packages and IC packages in FIGS. 1A-1B and 3A-3D;

FIGS. 5A-5C is a flowchart illustrating another exemplary fabrication process of fabricating a die package with entangled vertical interconnects coupled to a routing substrate of the die package, wherein the die package can be provided in an IC package and coupled to an interposer substrate to provide signal routing paths between a second electrical component coupled to the interposer substrate and the die package in the IC package, including, but not limited to, the die packages and IC packages in FIGS. 1A-1B and 3A-3D;

FIGS. 6A-6F are exemplary fabrication stages during fabrication of the die package and IC package according to the exemplary fabrication process in FIGS. 5A-5C;

FIG. 7 is a block diagram of an exemplary wireless communications device that includes one or more IC packages that include a die package with entangled vertical interconnects coupled to a routing substrate of the die package, wherein the die package can be provided in an IC package and coupled to an interposer substrate to provide signal routing paths between a second electrical component coupled to the interposer substrate and the die package in the IC package, including, but not limited to, the die packages and IC packages in FIGS. 1A-1B, 3A-3D, and 6D-6F, and that can be fabricated according to a fabrication process including, but not limited to, the exemplary fabrication processes in FIGS. 4 and 5A-5C; and

FIG. 8 is a block diagram of an exemplary electronic device in the form of a processor-based system that includes or more IC packages that include a die package with entangled vertical interconnects between a routing substrate of the die package and the interposer substrate to provide signal routing paths between a second electrical component and the die package, including, but not limited to, the die packages and IC packages in FIGS. 1A-1B, 3A-3D, and 6D-6F, and that can be fabricated according to a fabrication process, including, but not limited to, the exemplary fabrication processes in FIGS. 4 and 5A-5C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a die package with entangled vertical interconnects coupled to a routing substrate for reduced routing substrate layers. Related integrated circuit (IC) packages and fabrication methods are also disclosed. The die package includes a first die coupled to a routing substrate (e.g., a package substrate, an embedded trace substrate (ETS)) for providing signal routing paths between external interconnects and the first die. The die package can be provided as part of an IC package that also includes a second electrical component (i.e., second die or second IC package) coupled to the die package and an interposer substrate disposed between the second electrical component and the die package. The interposer substrate has metal interconnects coupled to the second electrical component and the die package to provide signal routing paths between the second electrical component and the die package. For example, the IC package could be a three-dimensional (3D) IC (3DIC) package where the second electrical component is a second, upper die that is coupled to the die package as a first, bottom die package in a vertical direction. The 3DIC package could be a package-on-package (POP) assembly that includes a second, upper die package with the second, upper die coupled to the first, bottom die package.

In exemplary aspects, the die package includes entangled vertical interconnects that are coupled metal interconnects in the routing substrate of the die package. Entangled vertical interconnects are vertical interconnects that are angled metal interconnects in the vertical direction between their coupled metal interconnects in the routing substrate of the die package. In this manner, the signal routing provided by the entangled vertical interconnects is not in a straight vertical direction between metal interconnects aligned in a straight vertical direction, but rather laterally offset in a horizontal direction between its coupled metal interconnects. In this manner, the entangled vertical interconnects are free from a design perspective to couple any metal interconnects together in an IC package even if such metal interconnects are not aligned in the vertical direction Also, as an example, the entangled vertical interconnects can be in a mold layer of the die package that encompasses the first die in the die package and is disposed adjacent to the first die in the horizontal direction. The entangled vertical interconnects can be coupled to respective metal interconnects in an interposer substrate to provide a signal routing path between the die package and the interposer substrate. For example, metal interconnects in the interposer substrate may not be aligned with the metal interconnects of the routing substrate in the vertical direction such that straight vertical interconnects can be used to couple the metal interconnects of the interposer substrate to the metal interconnects of the routing substrate of the die package. Thus, the entangled vertical interconnects can provide signal routing paths between coupled metal interconnects in the interposer substrate and the routing substrate of the die package that are not vertically aligned to each other. For example, it may be desired for the die interconnects and metal interconnects of the interposer substrate to have a different pitch from the metal interconnects of the routing substrate of the die package.

In this manner, it is not necessary for the interposer substrate or the routing substrate of the die package to have entangled interconnects to support interconnections between the interposer substrate and the routing substrate that may not be vertically aligned and/or have the same pitch. In this manner, as an example, if the interposer substrate is provided to couple the second electrical component having die interconnects with a different pitch from the metal interconnects of the routing substrate, the entangled interconnects do not have to be provided in the interposer substrate or the routing substrate. The entangled interconnects can be provided as the vertical interconnects in the die package between the die package and the interposer substrate. For example, the entangled vertical interconnects may be disposed in a mold layer of the die package that is disposed on the routing substrate and encompasses and is laterally adjacent in the horizontal direction to the first die. As an example, the entangled vertical interconnects can be provided as wire bonds in the mold layer that are coupled to metal interconnects of the interposer substrate and the routing substrate. In this manner, the wire bonds are able to be bent at an angle to provide entangled vertical interconnects between the interposer substrate and the routing substrate.

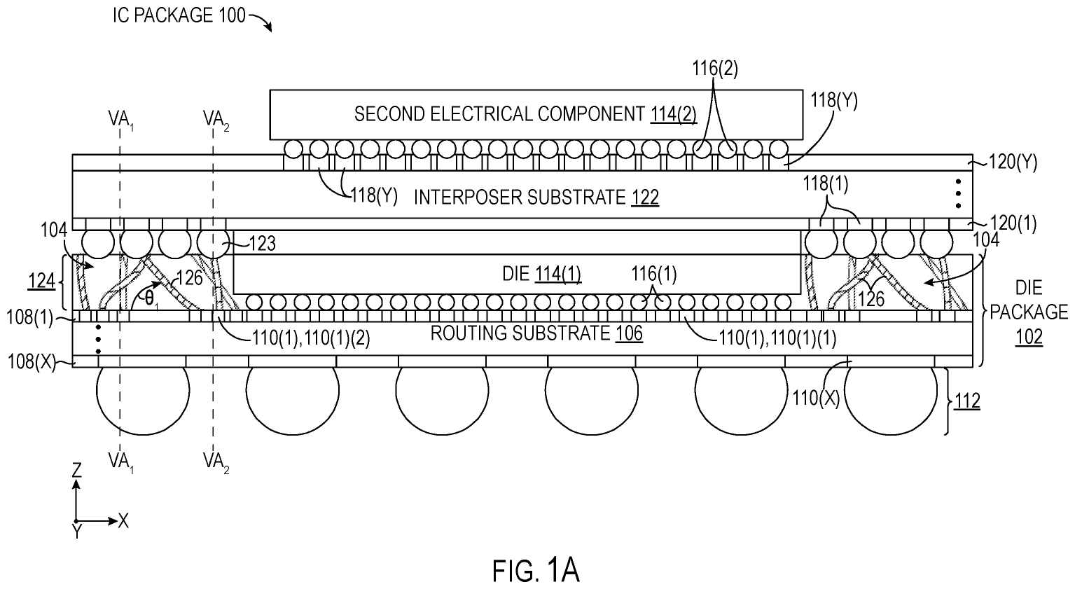

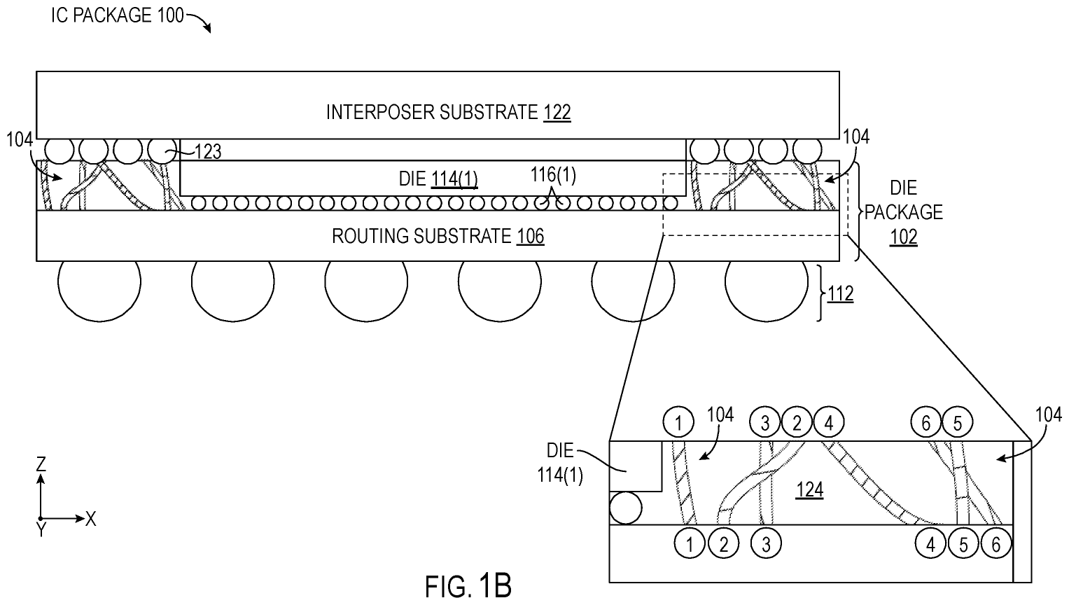

In this regard, FIGS. 1A and 1B are side views of an exemplary integrated circuit (IC) package 100 that includes a die package 102 with entangled vertical interconnects 104 coupled to a routing substrate 106 of the die package 102. As discussed in more detail below, the entangled vertical interconnects 104 are metal interconnects (e.g., wire bonds) that can extend in the second, vertical direction (Z-axis direction) at an angle @1 (e.g., an acute angle) with respect to the vertical axis VA1 in the second, vertical direction (Z-axis direction) to provide signal routing paths to the routing substrate 106. This is shown in more detail in FIG. 1B, where it is shown that the entangled vertical interconnects 104 can be routed laterally in the first, horizontal direction(s) (X-axis and/or Y-axis direction(s)) between metal interconnects that are not aligned in the second, vertical direction (Z-axis direction). Thus, the entangled vertical interconnects 104 are free from a design perspective to be routed laterally in the first, horizontal direction(s) (X-axis and/or Y-axis directions) between different metal interconnects to provide signal routing freedom in the die package 102. The routing substrate 106 extends in the first, horizontal direction(s) (X-axis and Y-axis directions). For example, the routing substrate 106 may be a package substrate or embedded trace substrate (ETS) that includes one or more metallization layers 108(1)-108(X) each with respective metal interconnects 110(1)-110(X) (e.g. metal lines, metal traces) disposed therein to provide signal routing paths in the routing substrate 106. In this manner, the routing substrate 106 provides signal routing paths to external interconnects 112 (e.g., solder balls, ball grid array (BGA) interconnects) of the IC package 100. The first metallization layer 108(1) of the routing substrate 106 includes first metal interconnects 110(1)(1) that are coupled to respective first die interconnects 116(1) of a first die 114(1) extending in the second, vertical direction (Z-axis direction) in the die package 102 to provide signal routing paths between the first die 114(1) and the routing substrate 106.

With continuing reference to FIG. 1A, the first metallization layer 108(1) of the routing substrate 106 also includes second metal interconnects 110(1)(2). The second metal interconnects 110(1)(2) are coupled to respective entangled vertical interconnects 104 on the die package 102 to also provide signal routing paths to the routing substrate 106. In this manner, the entangled vertical interconnects 104 can be coupled to respective third metal interconnects 118(1) in a third metallization layer 120(1) in an interposer substrate 122 to provide signal routing paths between the die package 102 and the interposer substrate 122. For example, the interposer substrate 122 can be a package substrate or an ETS, as examples. This in turn can provide signal routing paths between a second electrical component 114(2) (e.g., as part of a second die or second IC package) and the routing substrate 106 to facilitate die-to-die (D2D) interconnects between the first die 114(1) and second electrical component 114(2) and/or between the second electrical component 114(2) and the external interconnects 112. Second component metal interconnects 116(2) (e.g., solder balls, BGA interconnects) of the second electrical component 114(2) are coupled to fourth metal interconnects 118(Y) of a fourth metallization layer 120(Y) of the interposer substrate 122. As shown in FIG. 1A, in this example, the third metal interconnects 118(1) of the interposer substrate 122 are coupled to external interconnects 123 (e.g., solder balls, BGA interconnects). The external interconnects 123 are coupled to respective entangled vertical interconnects 104 to provide signal routing paths between the interposer substrate 122 and the routing substrate 106 through the entangled vertical interconnects 104 coupling to the second metal interconnects 110(1)(2) of the first metallization layer 108(1). The external interconnects 112 are coupled to the routing substrate 106 through metal interconnects 110(X) in the second metallization layer 108(X) of the routing substrate 106.

The third metal interconnects 118(1) in the third metallization layer 120(1) of the interposer substrate 122 may not be aligned with the second metal interconnects 110(1)(2) of the routing substrate 106 in the second, vertical direction (Z-axis direction) such that straight vertical interconnects can be used to couple the third metal interconnects 118(1) of the interposer substrate 122 to the second metal interconnects 110(1)(2) of the routing substrate 106. In other words, there may be second metal interconnects 110(1)(2) whose vertical axis VA1 does not intersect the vertical axis VA2 of a next more closely located third metal interconnect 118(1) of the interposer substrate 122 in the first, horizontal direction (X-axis and/or Y-axis direction(s)). However, the entangled vertical interconnects 104 can provide signal routing paths between coupled third and second metal interconnects 118(1), 110(1)(2) of the interposer substrate 122 and the routing substrate 106, respectively, that are not vertically aligned to each other in the second, vertical direction (Z-axis direction). For example, it may be desired for the third metal interconnects 118(1) of the interposer substrate 122 and the second metal interconnects 110(1)(2) of the routing substrate 106 to have a different pitch and thus not be aligned in the second, vertical direction (Z-axis direction). Thus, by providing the angled, entangled vertical interconnects 104 to couple the interposer substrate 122 to the routing substrate 106 in the second, vertical direction (Z-axis direction), the freedom exists to laterally displace the entangled vertical interconnects 104 between the routing substrate 106 and the interposer substrate 122 to provide more freedom in routing without the third metal interconnects 118(1) of the interposer substrate 122 and the second metal interconnects 110(1)(2) of the interposer substrate 122 having to be aligned and/or the same pitch.

In this manner, it is not necessary for the interposer substrate 122 or the routing substrate 106 of the die package 102 to have entangled interconnects to support interconnections between the interposer substrate 122 and the routing substrate 106 that may not be vertically aligned in the second, vertical direction (Z-axis direction) and/or have the same pitch. In this manner, as an example, if the interposer substrate 122 is provided to couple the second electrical component 114(2) having the second component metal interconnects 116(2) with a different pitch from the second metal interconnects 110(1)(2) of the routing substrate 106, the entangled vertical interconnects 104 do not have to be provided in the interposer substrate 122 or the routing substrate 106. The entangled vertical interconnects 104 can be provided as vertical interconnects in the die package 102 between the die package 102 and the interposer substrate 122 in the second, vertical direction (Z-axis direction) as shown in FIG. 1A. For example, the entangled vertical interconnects 104 may be at least partially disposed in a mold layer 124 of the die package 102 that is formed from disposing a mold material on the routing substrate 106 to encompass and be disposed laterally adjacent in the first, horizontal direction (X-axis and/or Y-axis direction(s)) to the first die 114(1). The entangled vertical interconnects 104 being at least partially disposed in the mold layer 124 provides support for the entangled vertical interconnects 104 to prevent the entangled vertical interconnects 104 from being damaged. As an example, as discussed in more detail below, the entangled vertical interconnects 104 can be provided as wire bonds 126 in the mold layer 124 that are coupled to the third metal interconnects 118(1) of the interposer substrate 122 and the second metal interconnects 110(1)(2) of the routing substrate 106. In this manner, the wire bonds 126 are able to be bent at an angle to provide entangled vertical interconnects 104 between the interposer substrate 122 and the routing substrate 106.

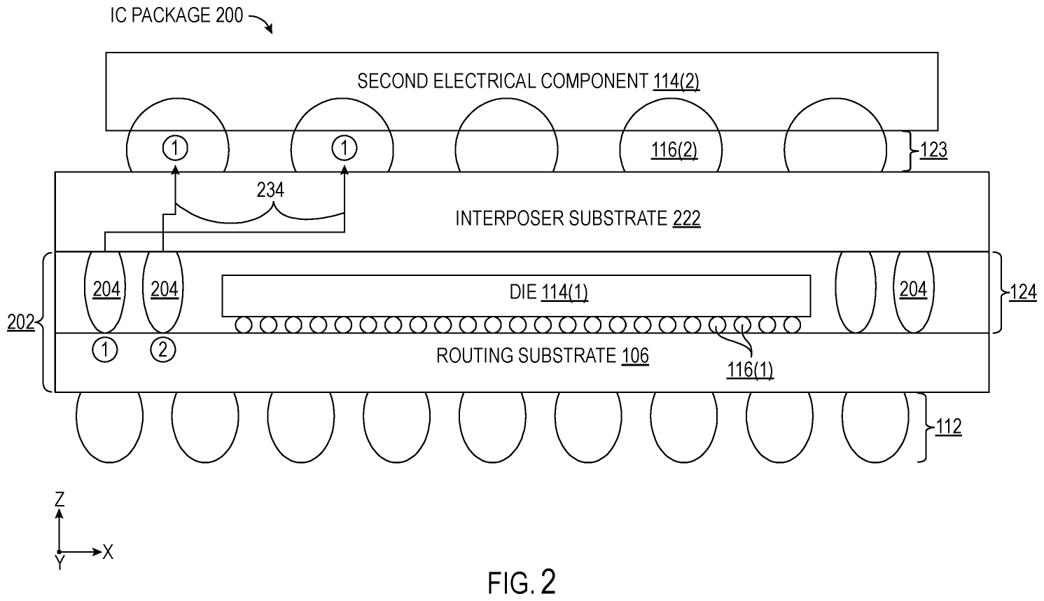

In contrast, FIG. 2 is a side view of another IC package 200 with an alternative die package 202 that includes non-entangled vertical interconnects 204 coupled to an alternative interposer substrate 222. Common elements between the IC package 200 in FIG. 2 and the IC package 100 in FIGS. 1A and 1B are shown with common element numbers. Because the die package 202 includes non-entangled vertical interconnects 204, the interposer substrate 222 includes entangled interconnects 234 to provide signal routing paths between the die package 202 and the second electrical component 114(2). As shown in FIG. 2, the entangled interconnects 234 are not aligned in the second, vertical direction (Z-axis direction) with the non-entangled vertical interconnects 204. This may add routing complexity to the interposer substrate 222 that may cause the interposer substrate 222 to either have to be enlarged in area in the first, horizontal direction(s) (X-axis and/or Y-axis direction(s)) and/or additional metallization layers added to the interposer substrate 222 to provide additional area for metal interconnects for signal routing.

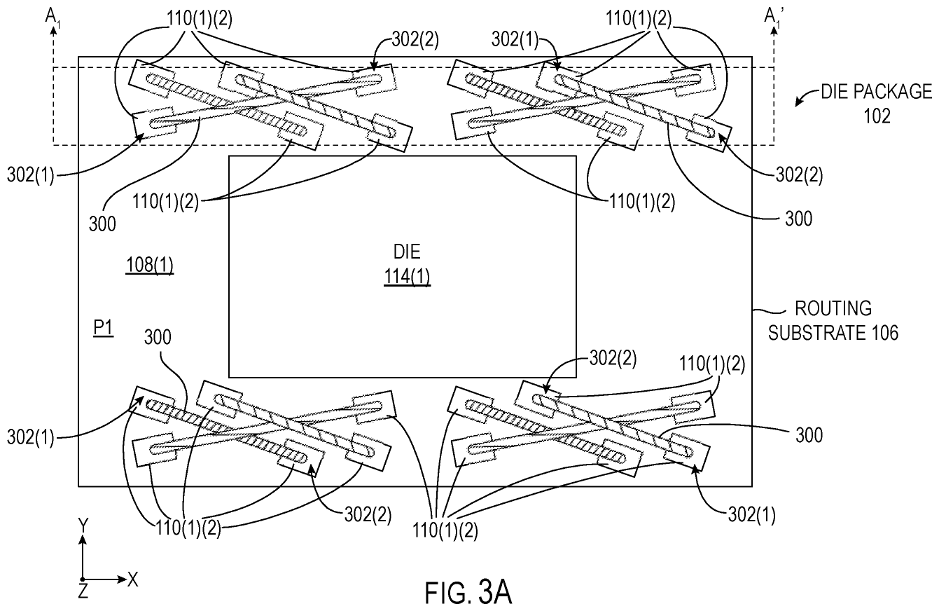

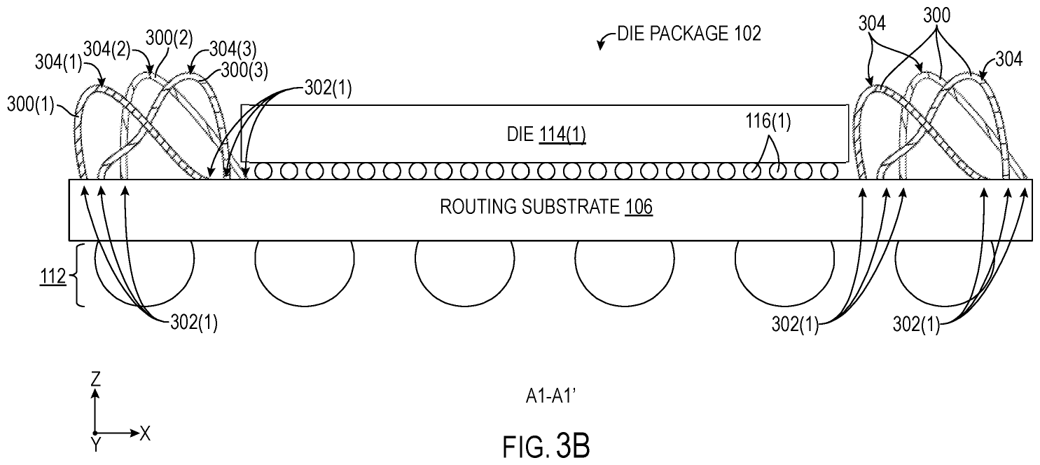

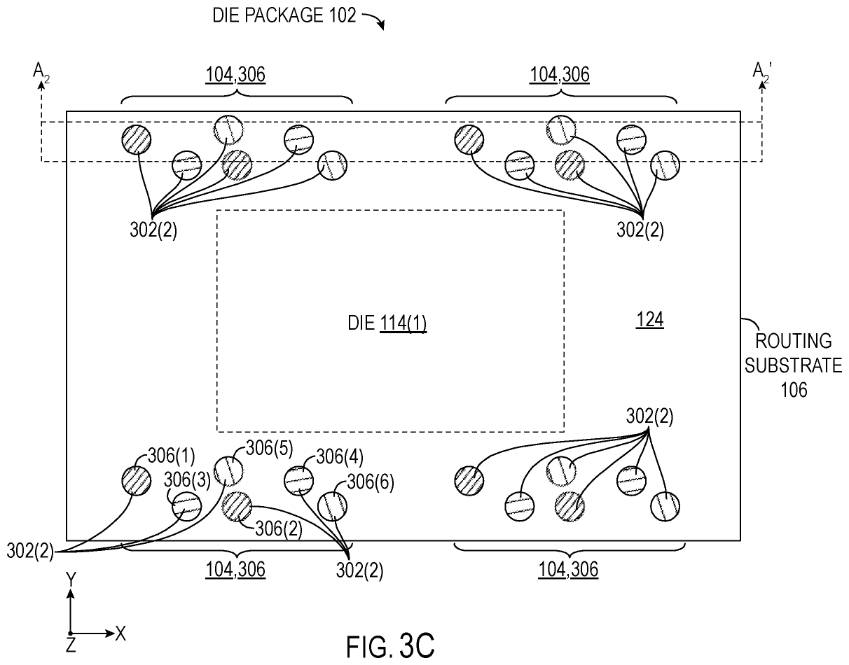

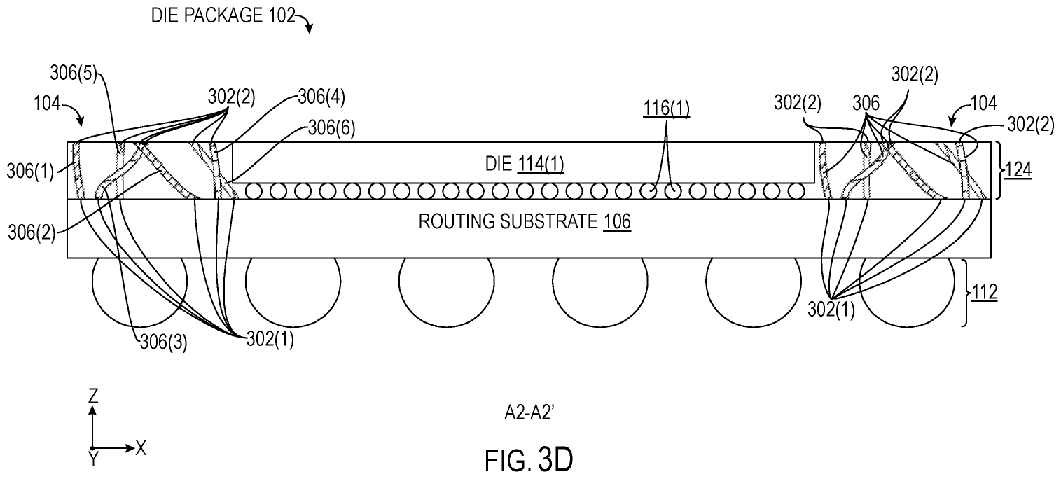

To provide more exemplary detail of the IC package 100 and its die package 102 in FIGS. 1A and 1B illustrating more exemplary detail of the entangled vertical interconnects 104, FIGS. 3A-3D are provided. FIG. 3A is a top view of the die package 102 of the IC package 100 in FIGS. 1A and 1B without the presence of the mold layer 124 in the die package 102. FIG. 3B is a side cross-sectional view of the die package 102 in FIG. 3A across the A1-A1′ cross-section line in FIG. 3A. FIG. 3C is a top view of the die package 102 in FIG. 3A after top sections of wire bond loops are removed to provide separate wire bonds as the entangled vertical interconnects 104 coupled to the routing substrate 106. FIG. 3D is a side view of the die package 102 in FIG. 3C with the entangled vertical interconnects 104 as wire bonds encompassed in the mold layer 124 of the die package 102.

In this regard, as illustrated in the top view of the die package 102 in FIG. 3A, the first die 114(1) is shown coupled to the first metallization layer 108(1) of the routing substrate 106. In this example, to form the entangled vertical interconnects 104 coupled to the routing substrate 106, wire bond loops 300 are first provided and coupled to the second metal interconnects 110(1)(2) of the routing substrate 106. Wire bond loops 300 are each wires that are coupled on both its ends 302(1), 302(2) to respective second metal interconnects 110(1)(2) of the routing substrate 106. The wire bond loops 300 are located and coupled to particular second metal interconnects 110(1)(2) of the routing substrate 106 so that the desired entangled connections are achieved once the wire bond loops 300 are processed to form the entangled vertical interconnects 104 like shown in the IC package 100 in FIGS. 1A and 1B. This is also shown in FIG. 3B as the cross-sectional side view of the die package 102 in FIG. 3A across the A1-A1′ cross-section line in FIG. 3A. The wire bond loops 300 each include a top section 304 where the wire bond loop 300 bends to create a radius. Note that as shown in FIG. 3A, because the wire bond loops 300 are connected at an angle laterally between two (2) second metal interconnects 110(1)(2) in the first, horizontal plane P1 (in the X-axis and Y-axis direction) of the routing substrate 106, when the wire bond loops 300 are processed by removing a portion of the wire bond loops 300 between its first ends 302(1), 302(2), the first ends 302(1) of the resulting two (2) separate entangled vertical interconnects 104 as wire bonds will be entangled with respect to its coupled second metal interconnects 110(1)(2), meaning that the first ends 302(1), 302(2) will not necessarily be aligned with its coupled second metal interconnects 110(1)(2) in the second, vertical direction (Z-axis direction).

FIG. 3C is a top view of the die package 102 after the entangled vertical interconnects 104 have been formed from processing the wire bond loops 300 shown in FIGS. 3A and 3B. After the mold layer 124 is disposed on the routing substrate 106 and the first die 114(1) and at least partially encompasses the wire bond loops 300 (see FIGS. 1A and 1B), the mold layer 124 is processed to remove a portion of the mold layer 124. For example, as discussed in more detail below, the mold layer 124 can be grinded down. As a result of this grinding or otherwise processing of the mold layer 124, a portion of the top sections 304 of the wire bond loops 300 (FIG. 3B) are also removed as a result. This causes each wire bond loop 300 to form two (2) separate wire bonds 306. For example, as shown in FIG. 3C, two (2) first wire bonds 306(1), 306(2) are shown as having been created by the removal of a first top section 304(1) of a first wire bond loop 300(1) as shown in FIG. 3B. Two (2) second wire bonds 306(3), 306(4) are shown as having been created by the removal of a second top section 304(2) of a second wire bond loop 300(2). Two (2) third wire bonds 306(5), 306(6) are shown as having been created by the removal of a third top section 304(3) of a third wire bond loop 300(3). The same is true for the other wire bond loops 300 in FIGS. 3A and 3B. The resulting wire bonds 306, 306(1)-306(6) will now have second ends 302(2) that are suspended above the routing substrate 106 in the second, vertical direction (Z-axis direction) as shown in FIG. 3D.

FIG. 3D is a side view of the die package 102 in FIG. 3C with the entangled vertical interconnects 104 as wire bonds 306, 306(1)-306(6) encompassed in the mold layer 124 of the die package 102. As shown in FIG. 3D, the wire bonds 306, 306(1)-306(6) have their first ends 302(1) coupled to the routing substrate 106 (the second metal interconnects 110(1)(2) of the routing substrate 106—see FIGS. 1A and 1B), and their second ends 302(2) suspended above the routing substrate 106 in the second vertical direction (Z-axis direction) in the mold layer 124. The second ends 302(2) of the wire bonds 306, 306(1)-306(6) are entangled from their respective first ends 302(1), meaning that the second ends 302(2) are not aligned in the second, vertical direction (Z-axis direction) from their first end 302(1). This means that when the interposer substrate 122 (see FIGS. 1A and 1B) is coupled to the die package 102, the location of the second ends 302(2) of the wire bonds 306, 306(1)-306(6) will dictate their connection points to the third metal interconnects 118(1) in the interposer substrate 122. In this manner, the connections between the routing substrate 106 and the interposer substrate 122 are entangled with each other through the entangled vertical interconnects 104 provided as the entangled wire bonds 306, 306(1)-306(6) in this example.

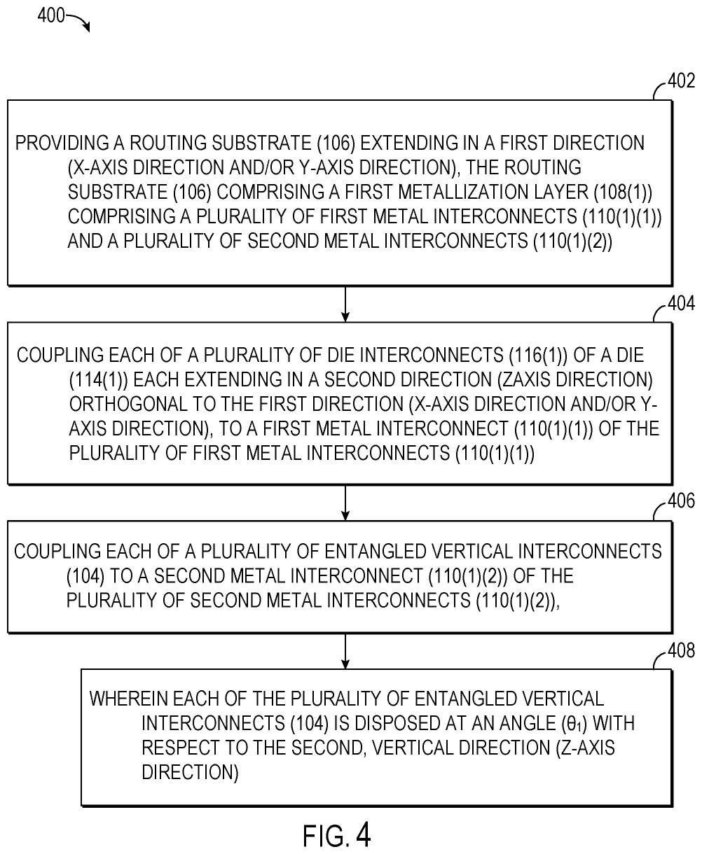

Die packages with entangled vertical interconnects coupled to a routing substrate of the die package, wherein the die package can be provided in an IC package and coupled to an interposer substrate to provide signal routing paths between a second electrical component coupled to the interposer substrate and the first die package in the IC package, including, but not limited to, the die package 102 and its IC package 100 in FIGS. 1A-1B and 3A-3D, can be fabricated according to a fabrication process. In this regard, FIG. 4 is a flowchart illustrating an exemplary fabrication process 400 of fabricating a die package and IC package, including, but not limited to, the die package 102 and its IC package 100 in FIGS. 1A-1B and 3A-3D, wherein the die package includes entangled vertical interconnects coupled to a routing substrate of the die package, wherein the die package can be provided in an IC package and coupled to an interposer substrate to provide signal routing paths between a second electrical component coupled to the interposer substrate and the first die package. The fabrication process 400 in FIG. 4 is discussed in reference to the die package 102 and its IC package 100 in FIGS. 1A-1B and 3A-3D, but such is not limiting.

In this regard, as shown in FIG. 4, the fabrication process 400 of fabricating the die package 102 and its IC package 100 can include providing a routing substrate 106 extending in a first direction (X-axis direction and/or Y-axis direction), wherein the routing substrate 106 comprises a first metallization layer 108(1) comprising a plurality of first metal interconnects 110(1)(1) and a plurality of second metal interconnects 110(1)(2) (block 402 in FIG. 4). The fabrication process 400 can also include coupling each of a plurality of die interconnects 116(1) of a die 114(1) each extending in a second direction (Z-axis direction) orthogonal to the first direction (X-axis direction and/or Y-axis direction), to a first metal interconnect 110(1)(1) of the plurality of first metal interconnects 110(1)(1) (block 404 in FIG. 4). The fabrication process 400 can also include coupling each of a plurality of entangled vertical interconnects 104 to a second metal interconnect 110(1)(2) of the plurality of second metal interconnects 110(1)(2) (block 406 in FIG. 4). Each of the plurality of entangled vertical interconnects 104) is disposed at an angle Θ₁ (e.g., an acute angle) with respect to the second, vertical direction (Z-axis direction) (block 408 in FIG. 4).

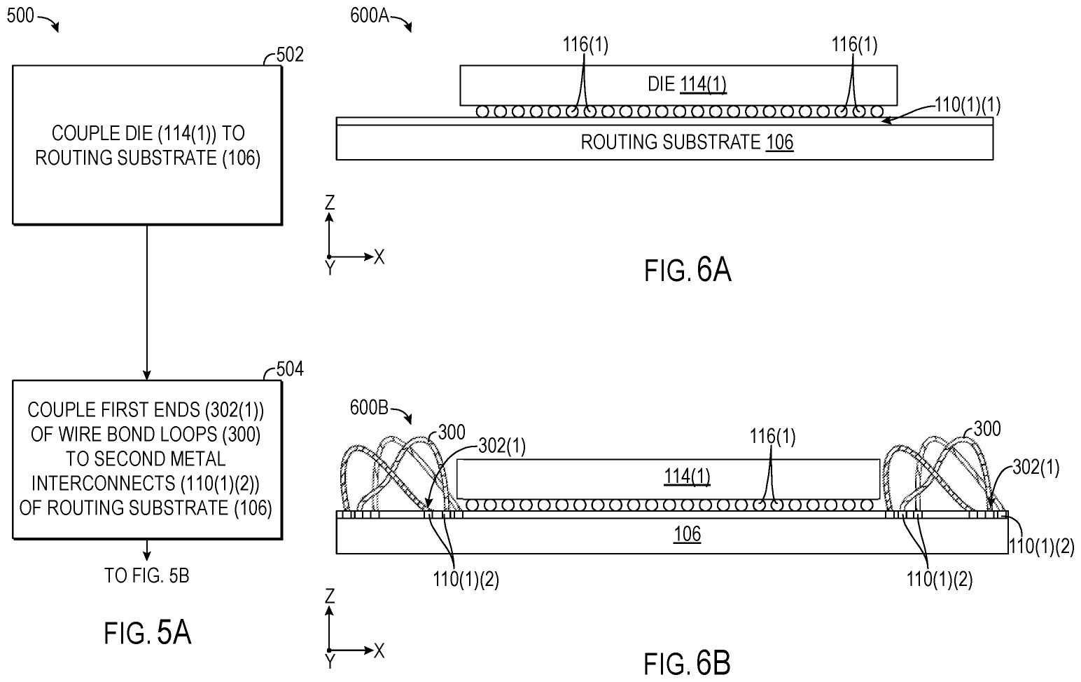

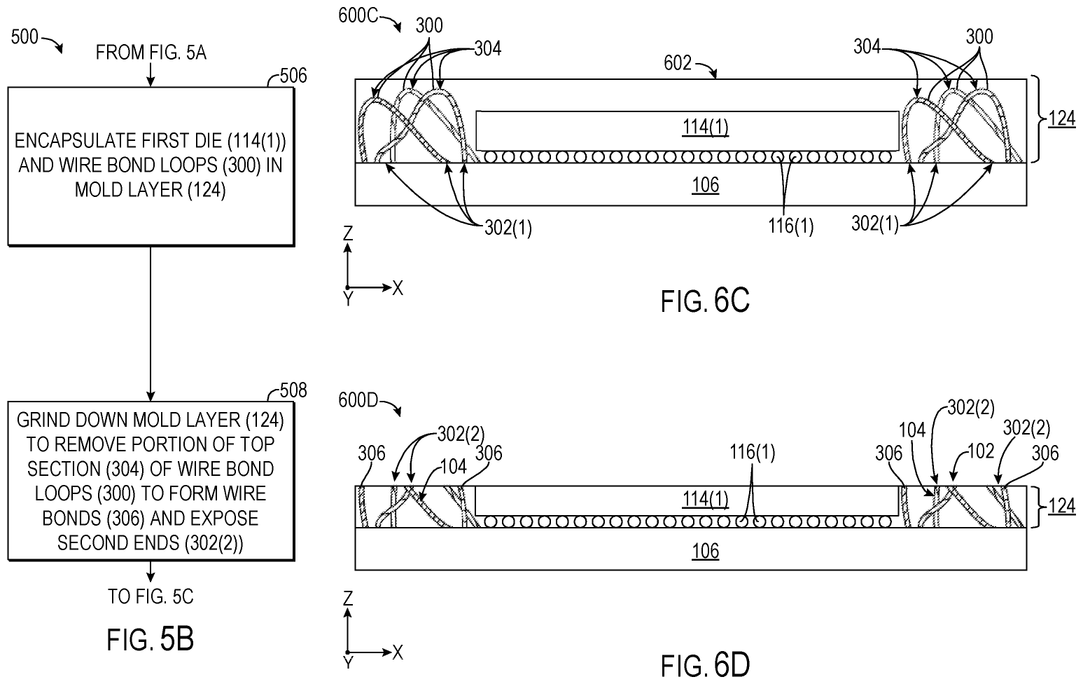

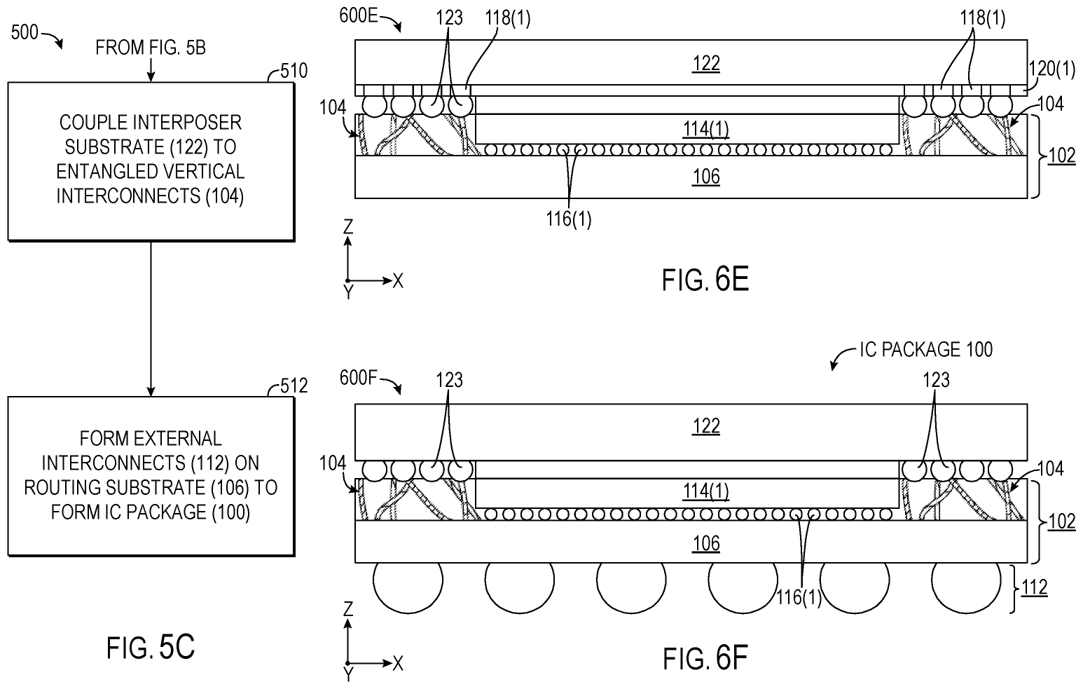

A die package with entangled vertical interconnects coupled to a routing substrate of the die package, wherein the die package can be provided in an IC package and coupled to an interposer substrate to provide signal routing paths between a second electrical component coupled to the interposer substrate and the die package in the IC package, including, but not limited to, the die packages and IC packages in FIGS. 1A-1B and 3A-3D, can be fabricated in other fabrication processes. For example, FIGS. 5A-5C is a flowchart illustrating another exemplary fabrication process 500 of fabricating a die package with entangled vertical interconnects coupled to a routing substrate of the die package, wherein the die package can be provided in an IC package and coupled to an interposer substrate to provide signal routing paths between a second electrical component coupled to the interposer substrate and the die package in the IC package, including, but not limited to, the die package 102 and its IC package 100 in FIGS. 1A-1B and 3A-3D. FIGS. 6A-6F are exemplary fabrication stages 600A-600F during fabrication of a die package and IC package according to the exemplary fabrication process 500 in FIGS. 5A-5C. The fabrication process 500 in FIGS. 5A-5C is discussed below with reference to the exemplary die package 102 and its IC package 100 in FIGS. 1A-1B, but such is not limiting.

In this regard, as shown in the exemplary fabrication stage 600A in FIG. 6A, a first step in the fabrication process 500 can be to couple the first die 114(1), and its first die interconnects 116(1), to the first metal interconnects 110(1)(1) of the routing substrate 106 (block 502 in FIG. 5A). Then, as shown in the exemplary fabrication stage 600B in FIG. 6B, a next step in the fabrication process 500 can be to couple the first ends 302(1) of wire bonds loops 300 that will eventually form the entangled vertical interconnects 104 as wire bonds 306 to the second metal interconnects 110(1)(2) of the routing substrate 106 (block 504 in FIG. 5A). As discussed above with regard to FIGS. 3A-3D, the wire bond loops 300 are wires that are coupled on both their first ends 302(1) to the routing substrate 106.

Then, as shown in the exemplary fabrication stage 600C in FIG. 6C, a next step in the fabrication process 500 can be to encapsulate the first die 114(1) and the wire bond loops 300 in a mold material 602 that is disposed on the routing substrate 106 to form the mold layer 124 (block 506 in FIG. 5B). As previously discussed, this can secure the wire bond loops 300 to protect their movement and damage as well as provide support to stabilize the wire bond loops for subsequent processing of the wire bond loops 300 performed in the next step (block 508 in FIG. 5B) to form the wire bonds 306 as the entangled vertical interconnects 104. Then, as shown in the exemplary fabrication stage 600D in FIG. 6D, a next step in the fabrication process 500 can be to grind down the mold layer 124 to remove a portion of the top sections 304 of the wire bond loops 300 to form two (2) separate wire bonds 306 from each wire bond loop 300 as the entangled vertical interconnects 104 (block 508 in FIG. 5B). The wire bonds 306 having been secured in the mold layer 124 retains their entangled orientation when they were formed as wire bond loops 300. The die package 102 is also formed in the fabrication stage 600D in FIG. 6D.

Then, as shown in the exemplary fabrication stage 600E in FIG. 6E, a next step in the fabrication process 500 can be to couple the interposer substrate 122, and more specifically the third metal interconnects 118(1) of the interposer substrate 122, through the external interconnects 123, to the entangled vertical interconnects 104 to electrically couple the interposer substrate 122 to the die package 102 (block 510 in FIG. 5C). The first ends 302(1) of the wire bonds 306 are already coupled to the routing substrate 106 as discussed above. The second ends 302(2) of the wire bonds 306 are coupled to the interposer substrate 122. Then, as shown in the exemplary fabrication stage 600F in FIG. 6F, a next step in the fabrication process 500 can be to form the external interconnects 112 in contact with the metal interconnects 110(X) of the routing substrate 106 to form the IC package 100 (block 512 in FIG. 5C). The second electrical component 114(2) shown in the IC package 100 in FIG. 1A could also then be coupled to the interposer substrate 122 as previously discussed.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Die packages with entangled vertical interconnects coupled to a routing substrate of the die package, wherein the die packages can be provided in an IC package and coupled to an interposer substrate to provide signal routing paths between a second electrical component coupled to the interposer substrate and the die package in the IC package, including, but not limited to, the die package 102 and its IC package 100 in FIGS. 1A-1B, 3A-3D, and 6D-6F, and that can be fabricated according to a fabrication process, including but not limited to the fabrication processes 400, 500 in FIGS. 4 and 5A-5C, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

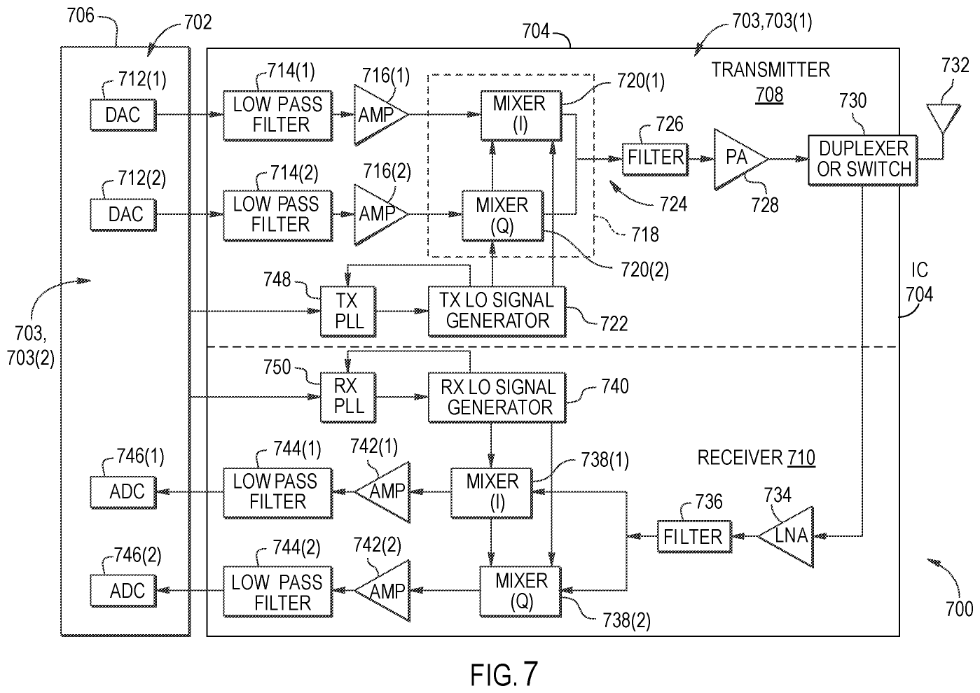

In this regard, FIG. 7 illustrates an exemplary wireless communications device 700 that includes one or more IC packages 702, 702(1), 702(2) that include die packages 703, 703(1)-703(2) including, but not limited to, the IC package 100 in FIGS. 1A-1B, 3A-3D, and 6F, and its die package 102 in FIGS. 1A-1B, 3A-3D, and 6D-6F, wherein the die packages include entangled vertical interconnects coupled to a routing substrate of the die package, wherein the die packages can be provided in an IC package and coupled to an interposer substrate to provide signal routing paths between a second electrical component coupled to the interposer substrate and the die package in the IC package.

The wireless communications device 700 may include or be provided in any of the above-referenced devices, as examples. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals, e.g., I and Q output currents, for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency upconversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Downconversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency upconversion, while the RX LO signal generator 740 generates the I and Q RX LO signals used for frequency downconversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

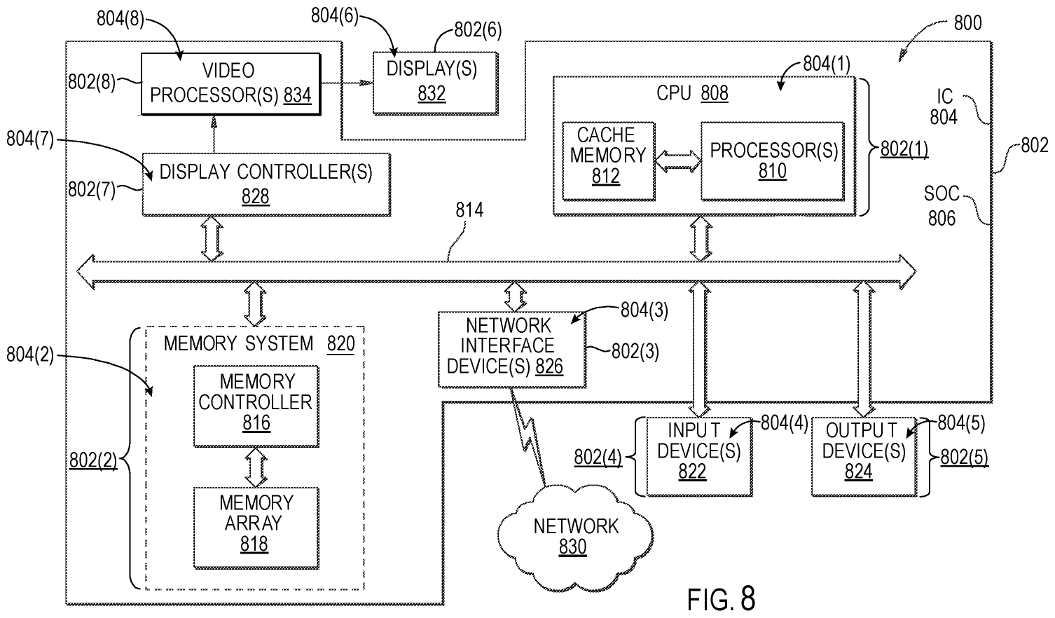

FIG. 8 illustrates an example of a processor-based system 800 that includes IC packages 802, 802(1)-802(8) that includes die packages 804, 804(1)-804(8) including, but not limited to, the IC package 100 in FIGS. 1A-1B, 3A-3D, and 6F, and its die package 102 in FIGS. 1A-1B, 3A-3D, and 6D-6F, wherein the die packages 804, 804(1) 804(8) include entangled vertical interconnects coupled to a routing substrate of the die package, wherein the die packages can be provided in the respective IC package 802, 802(1)-802(8) and coupled to an interposer substrate to provide signal routing paths between a second electrical component coupled to the interposer substrate and the die package 804, 804(1)-804(8) in the respective IC package 802, 802(1)-802(8), and wherein the IC packages 802, 802(1)-802(8) and their die packages 804, 804(1)-804(8) can be fabricated according to a fabrication process, including, but not limited to, the exemplary fabrication processes 400, 500 in FIGS. 4 and 5A-5C, and according to any aspects disclosed herein.

In this example, the processor-based system 800 may be included in an IC package 802, such as a system-on-a-chip (SoC) 806. The processor-based system 800 includes a CPU 808 that includes one or more processors 810, which may also be referred to as CPU cores or processor cores. The CPU 808 can be provided in an IC package 802(1) that includes the die package 804(1). The CPU 808 may have cache memory 812 coupled to the CPU 808 for rapid access to temporarily stored data. The CPU 808 is coupled to a system bus 814 and can intercouple master and slave devices included in the processor-based system 800. As is well known, the CPU 808 communicates with these other devices by exchanging address, control, and data information over the system bus 814. For example, the CPU 808 can communicate bus transaction requests to a memory controller 816 as an example of a slave device. Although not illustrated in FIG. 8, multiple system buses 814 could be provided, wherein each system bus 814 constitutes a different fabric.

Other master and slave devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. The memory system 820 can be provided in an IC package 802(2) that includes the die package 804(2). The network interface devices 826 can be provided in an IC package 802(3) that includes the die package 804(3). Each of the memory system 820, the one or more input devices 822, the one or more output devices 824, the one or more network interface devices 826, and the one or more display controllers 828 can be provided in the same or different circuit packages. The input devices 822 and/or the output devices 824 can be provided in a respective IC package 802(4), 802(5) that includes a respective die package 804(4), 804(5). The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU 808 may also be configured to access the display controller(s) 828 over the system bus 814 to control information sent to one or more displays 832. The display 832 can include or be provided in an IC package 802(6) that includes the die package 804(6). The display controller(s) 828 sends information to the display(s) 832 to be displayed via one or more video processors 834, which process the information to be displayed into a format suitable for the display(s) 832. The display controller(s) 828 and video processor(s) 834 can be provided in a respective IC package 802(7), 802(8) that includes the die package 804(7), 804(8), or be provided in the same IC package 802, or be provided in the same IC package 802(1) containing the CPU 808 as an example. The display(s) 832 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A die package, comprising:
a routing substrate extending in a first direction, the routing substrate comprising a first metallization layer comprising a plurality of first metal interconnects and a plurality of second metal interconnects;
a die comprising a plurality of die interconnects each extending in a second direction orthogonal to the first direction, each die interconnect of the plurality of die interconnects coupled to a first metal interconnect of the plurality of first metal interconnects; and
a plurality of entangled vertical interconnects coupled to a second metal interconnect of the plurality of second metal interconnects,
   each of the plurality of entangled vertical interconnects disposed at an angle with respect to the second direction.
      2. The die package of clause 1, further comprising a mold layer disposed on the first metallization layer;
wherein each of the plurality of entangled vertical interconnects is at least partially disposed in the mold layer.
   3. The die package of clause 1 or 2, wherein the plurality of entangled vertical interconnects comprises a plurality of wire bonds.
   4. The die package of any of clauses 1-3 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
   5. A method of fabricating an integrated circuit (IC) package, comprising:
fabricating a die package, comprising:
   providing a routing substrate extending in a first direction, the routing substrate comprising a first metallization layer comprising a plurality of first metal interconnects and a plurality of second metal interconnects;
   coupling each of a plurality of die interconnects of a die each extending in a second direction orthogonal to the first direction, to a first metal interconnect of the plurality of first metal interconnects; and
   coupling each of a plurality of entangled vertical interconnects to a second metal interconnect of the plurality of second metal interconnects,
   wherein each of the plurality of entangled vertical interconnects is disposed at an angle with respect to the second direction.
      6. The method of clause 5, further comprising disposing a mold material on the first metallization layer at least partially encompassing each of the plurality of entangled vertical interconnects in a mold layer and the die.
      7. The method of clause 5 or 6, wherein the plurality of entangled vertical interconnects comprises a plurality of entangled wire bonds.
      8. The method of clause 7, further comprising:
forming a plurality of wire bond loops each comprising a first end coupled to a second metal interconnect of the plurality of second metal interconnects and a second end opposite the first end coupled to another second metal interconnect of the plurality of second metal interconnects; and
removing a portion of each of the plurality of wire bond loops between the first end and the second end of each of the plurality of wire bond loops to form two (2) entangled wire bonds from each wire bond loop of the plurality of wire bond loops,
wherein the plurality of entangled wire bonds comprises the two (2) entangled wire bonds from each wire bond loop of the plurality of wire bond loops.
   9. The method of clause 8, further comprising disposing a mold material on the die on the first metallization layer at least partially encompassing each of the plurality of entangled wire bonds and the die.
   10. The method of clause 8 or 9, wherein removing the portion of each of the plurality of wire bond loops further comprises grinding down a top section of each of the plurality of wire bond loops between the first end and the second end of each of the plurality of wire bond loops to form the two (2) entangled wire bonds from each wire bond loop of the plurality of wire bond loops.
   11. The method of any of clauses 5-10, further comprising:
providing an interposer substrate comprising a second metallization layer comprising a plurality of third metal interconnects; and coupling each of the plurality of entangled vertical interconnects to a third metal
interconnect of the plurality of third metal interconnects.
   12. The method of clause 11, further comprising:
providing a second electrical component comprising a plurality of second metal interconnects; and
coupling each second component metal interconnect of the plurality of second metal interconnects to a third metal interconnect of the plurality of third metal interconnects.
   13. The method of clause 12, wherein the interposer substrate further comprises a third metallization layer comprising a plurality of fourth metal interconnects each coupled to a third metal interconnect of the plurality of third metal interconnects; and
further comprising coupling each second component metal interconnect of the plurality of second component metal interconnects to a fourth metal interconnect of the plurality of fourth metal interconnects to be coupled to the third metal interconnect of the plurality of fourth metal interconnects.
   14. An integrated circuit (IC) package, comprising:
a first die package, comprising:
   a first routing substrate extending in a first direction, the first routing substrate comprising a first metallization layer comprising a plurality of first metal interconnects and a plurality of second metal interconnects;
   a first die comprising a plurality of first die interconnects each extending in a second direction orthogonal to the first direction,
      each first die interconnect of the plurality of first die interconnects coupled to a first metal interconnect of the plurality of first metal interconnects; and
   a plurality of entangled vertical interconnects coupled to a second metal interconnect of the plurality of second metal interconnects,
      each of the plurality of entangled vertical interconnects disposed at an angle with respect to the second direction; and
an interposer substrate adjacent to the first die package in the second direction, the interposer substrate comprising:
   a second metallization layer comprising a plurality of third metal interconnects each coupled to an entangled vertical interconnect of the plurality of entangled vertical interconnects.
      15. The IC package of clause 14, wherein each of the plurality of entangled vertical interconnects is coupled to a second metal interconnect of the plurality of second metal interconnects unaligned in the second direction to a coupled third metal interconnect of the plurality of third metal interconnects.
      16. The IC package of clause 14, wherein each second metal interconnect of the plurality of second metal interconnects does not intersect an axis in the second direction of a third metal interconnect of the plurality of third metal interconnects coupled together through an entangled vertical interconnect of the plurality of entangled vertical interconnects.
      17. The IC package of any of clauses 14-16, further comprising a second electrical component comprising a plurality of second component metal interconnects each extending in the second direction, each second metal interconnect of the plurality of second component metal interconnects coupled to a third metal interconnect of the plurality of third metal interconnects.
      18. The IC package of clause 17, wherein the second electrical component comprises a second IC package comprising:
a second routing substrate extending in the first direction, the second routing substrate comprising a third metallization layer comprising a plurality of fourth metal interconnects; and
the plurality of second component metal interconnects;
wherein:
   each second metal interconnect of the plurality of second metal interconnects is coupled to a fourth metal interconnect of the plurality of fourth metal interconnects; and
   each fourth metal interconnect of the plurality of fourth metal interconnects is further coupled to a third metal interconnect of the plurality of third metal interconnects.
      19. The IC package of clause 17 or 18, wherein the interposer substrate further comprises a third metallization layer adjacent to the second die in the second direction,
the third metallization layer comprises a plurality of fourth metal interconnects each coupled to a third metal interconnect of the plurality of third metal interconnects and a second component metal interconnect of the plurality of second component metal interconnects.
   20. The IC package of any of clauses 14-19, wherein the first die package further comprises a mold layer disposed on the first metallization layer;
wherein each of the plurality of entangled vertical interconnects is at least partially disposed in the mold layer.

What is claimed is:

1. A die package, comprising:
a routing substrate extending in a first direction, the routing substrate comprising a first metallization layer comprising a plurality of first metal interconnects and a plurality of second metal interconnects;
a die comprising a plurality of die interconnects each extending in a second direction orthogonal to the first direction,
each die interconnect of the plurality of die interconnects coupled to a first metal interconnect of the plurality of first metal interconnects; and
a plurality of entangled vertical interconnects coupled to a second metal interconnect of the plurality of second metal interconnects,
each of the plurality of entangled vertical interconnects disposed at an angle with respect to the second direction.

2. The die package of claim 1, further comprising a mold layer disposed on the first metallization layer;
wherein each of the plurality of entangled vertical interconnects is at least partially disposed in the mold layer.

3. The die package of claim 1, wherein the plurality of entangled vertical interconnects comprises a plurality of wire bonds.

4. The die package of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

5. A method of fabricating an integrated circuit (IC) package, comprising:
fabricating a die package, comprising:
providing a routing substrate extending in a first direction, the routing substrate comprising a first metallization layer comprising a plurality of first metal interconnects and a plurality of second metal interconnects;
coupling each of a plurality of die interconnects of a die each extending in a second direction orthogonal to the first direction, to a first metal interconnect of the plurality of first metal interconnects; and
coupling each of a plurality of entangled vertical interconnects to a second metal interconnect of the plurality of second metal interconnects,
wherein each of the plurality of entangled vertical interconnects is disposed at an angle with respect to the second direction.

6. The method of claim 5, further comprising disposing a mold material on the first metallization layer at least partially encompassing each of the plurality of entangled vertical interconnects in a mold layer and the die.

7. The method of claim 5, wherein the plurality of entangled vertical interconnects comprises a plurality of entangled wire bonds.

8. The method of claim 7, further comprising:
forming a plurality of wire bond loops each comprising a first end coupled to a second metal interconnect of the plurality of second metal interconnects and a second end opposite the first end coupled to another second metal interconnect of the plurality of second metal interconnects; and
removing a portion of each of the plurality of wire bond loops between the first end and the second end of each of the plurality of wire bond loops to form two (2) entangled wire bonds from each wire bond loop of the plurality of wire bond loops,
wherein the plurality of entangled wire bonds comprises the two (2) entangled wire bonds from each wire bond loop of the plurality of wire bond loops.

9. The method of claim 8, further comprising disposing a mold material on the die on the first metallization layer at least partially encompassing each of the plurality of entangled wire bonds and the die.

10. The method of claim 8, wherein removing the portion of each of the plurality of wire bond loops further comprises grinding down a top section of each of the plurality of wire bond loops between the first end and the second end of each of the plurality of wire bond loops to form the two (2) entangled wire bonds from each wire bond loop of the plurality of wire bond loops.

11. The method of claim 5, further comprising:
providing an interposer substrate comprising a second metallization layer comprising a plurality of third metal interconnects; and
coupling each of the plurality of entangled vertical interconnects to a third metal interconnect of the plurality of third metal interconnects.

12. The method of claim 11, further comprising:
providing a second electrical component comprising a plurality of second metal interconnects; and
coupling each second component metal interconnect of the plurality of second metal interconnects to a third metal interconnect of the plurality of third metal interconnects.

13. The method of claim 12, wherein the interposer substrate further comprises a third metallization layer comprising a plurality of fourth metal interconnects each coupled to a third metal interconnect of the plurality of third metal interconnects; and
further comprising coupling each second component metal interconnect of the plurality of second component metal interconnects to a fourth metal interconnect of the plurality of fourth metal interconnects to be coupled to the third metal interconnect of the plurality of fourth metal interconnects.

14. An integrated circuit (IC) package, comprising:
a first die package, comprising:
a first routing substrate extending in a first direction, the first routing substrate comprising a first metallization layer comprising a plurality of first metal interconnects and a plurality of second metal interconnects;
a first die comprising a plurality of first die interconnects each extending in a second direction orthogonal to the first direction,
each first die interconnect of the plurality of first die interconnects coupled to a first metal interconnect of the plurality of first metal interconnects; and
a plurality of entangled vertical interconnects coupled to a second metal interconnect of the plurality of second metal interconnects,
each of the plurality of entangled vertical interconnects disposed at an angle with respect to the second direction; and
an interposer substrate adjacent to the first die package in the second direction, the interposer substrate comprising:
a second metallization layer comprising a plurality of third metal interconnects each coupled to an entangled vertical interconnect of the plurality of entangled vertical interconnects.

15. The IC package of claim 14, wherein each of the plurality of entangled vertical interconnects is coupled to a second metal interconnect of the plurality of second metal interconnects unaligned in the second direction to a coupled third metal interconnect of the plurality of third metal interconnects.

16. The IC package of claim 14, wherein each second metal interconnect of the plurality of second metal interconnects does not intersect an axis in the second direction of a third metal interconnect of the plurality of third metal interconnects coupled together through an entangled vertical interconnect of the plurality of entangled vertical interconnects.

17. The IC package of claim 14, further comprising a second electrical component comprising a plurality of second component metal interconnects each extending in the second direction,
each second metal interconnect of the plurality of second component metal interconnects coupled to a third metal interconnect of the plurality of third metal interconnects.

18. The IC package of claim 17, wherein the second electrical component comprises a second IC package comprising:
a second routing substrate extending in the first direction, the second routing substrate comprising a third metallization layer comprising a plurality of fourth metal interconnects; and
the plurality of second component metal interconnects;
wherein:
each second metal interconnect of the plurality of second metal interconnects is coupled to a fourth metal interconnect of the plurality of fourth metal interconnects; and
each fourth metal interconnect of the plurality of fourth metal interconnects is further coupled to a third metal interconnect of the plurality of third metal interconnects.

19. The IC package of claim 17, wherein the interposer substrate further comprises a third metallization layer adjacent to the second die in the second direction,
the third metallization layer comprises a plurality of fourth metal interconnects each coupled to a third metal interconnect of the plurality of third metal interconnects and a second component metal interconnect of the plurality of second component metal interconnects.

20. The IC package of claim 14, wherein the first die package further comprises a mold layer disposed on the first metallization layer;
wherein each of the plurality of entangled vertical interconnects is at least partially disposed in the mold layer.
